(19) United States
(12) Patent Application Publication
(10) Pub. No.: US 2008/0197437 A1
(43) Pub. Date: Aug. 21, 2008

(54) Solid-state imaging apparatus, manufacturing method therefor and electronic equipment using the same

(75) Inventors: Tomonobu Sugimoto, Fukui (JP); Takashi Magoi, Fukui (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/068,927

(22) Filed: Feb. 13, 2008

(30) Foreign Application Priority Data
Feb. 21, 2007 (JP) 41392/2007

(51) Int. Cl. H01L 31/0232; H01L 31/18

(52) U.S. Cl. 257/432; 438/65; 257/E31.127

(57) ABSTRACT

Provided is a solid-state imaging apparatus having excellent reading accuracy. The solid-state imaging apparatus of the present invention includes a solid-state imaging element (light receiving element portion) (1a) of a solid-state imaging element chip (1) mounted on a film (11), and a resin (2b) having fluidity between the solid-state imaging element chip (1) and the film (11), in which the periphery of the resin having the fluidity is sealed with solid-state resins (2a, 14, etc.) that are said to be sealing members. The resin (2b) having the fluidity eliminates an adverse influence on reading due to waviness on the film surface, and realizes the solid-state imaging apparatus having the excellent reading accuracy.

### BACKGROUND OF THE INVENTION

1. Field of the Invention

The present invention relates to a solid-state imaging apparatus, and more particularly, to a structure of and a manufacturing method for the solid-state imaging apparatus used for a contact optical sensor that detects a surface configuration of an object, such as a fingerprint sensor for authenticating a fingerprint.

2. Description of Related Art

Over the recent years, there has been an increasing need for authenticating the individuals based on biometric patterns. In the biometric patterns, the fingerprint authentication is defined as a biometric authentication method that is the oldest in history and has a proven result. A fingerprint input apparatus using a rigid substrate such as glass epoxy and ceramic has been utilized over the years. A variety of fingerprint input apparatuses and optical sensor units, which can be downsized and thinned, are disclosed.

For example, JP 2005-18595 A (hereinafter, referred to as Patent Document 1) discloses a fingerprint input apparatus using a solid-state imaging element (sweep sensor) in a scattered light direct reading system. FIG. 1 illustrates a typical example thereof. In FIG. 1, reference numeral 130 represents a protection member. Patent Document 1 further discloses that a transparent plastic sheet can be used as a material of the protection member. Further, a silicon substrate is especially preferable in terms of providing a low cost and reading a minute image. Moreover, Patent Document 1 discloses that the protection member 130 is bonded onto a solid-state imaging element 101a of a solid-state imaging element substrate 101.

A specific bonding method thereof is disclosed, in which when sticking the protection member 130 to the solid-state imaging element substrate 101, a bonding resin (sealing resin) 111 is applied over a side of the solid-state imaging element substrate 101, and thereafter the protection member 130 is stuck thereto, whereby the protection member 130 can be bonded in a way that prevents the seeping bonding resin 111 from flowing round an upper surface of the protection member 130.

Further, Patent Document 1 discloses that an area getting deficient in the bonding resin 111 can be replenished from the periphery, and, in this case, the bonding resin 111 has a function as a sealing resin.

As a method that does not use a special protection member, for example, as shown by the typical example of FIG. 2, JP03-142880 A (hereinafter, referred to as Patent Document 2) discloses that a transparent film substrate 211 is mounted with a semiconductor image sensor chip 213 having a light receiving element 214 via a transparent photo-curing insulation resin 216. Patent Document 2 further discloses that the transparent photo-curing insulation resin 216 is irradiated with ultraviolet rays via the transparent film substrate 211 and is thus hardened, thereby completing the mounting thereof.

Moreover, Patent Document 2 discloses, though not illustrated, an image sensor unit, i.e., a solid-state imaging apparatus including light emitting diodes provided on the transparent film substrate, in which information of the light beams guided by the light receiving elements is converted into image output signals through the semiconductor image sensor chip and input/output circuit components, and an original sheet placed on the upper surface (opposite to a mounting surface of the semiconductor image sensor chip etc.) of the transparent film substrate is read.

Further, JP 2004-173827 A (hereinafter, referred to as Patent Document 3) discloses an optical sensor that can be downsized and thinned. An optical imaging element 340 is formed via an isolation layer on an unillustrated manufacturing substrate, thereafter peeled off from the manufacturing substrate, and bonded to a plastic sheet 311 as a sheet-shaped substrate shown in FIG. 3. On this occasion, the optical imaging element is formed on the unillustrated isolation layer. Thereafter, an unillustrated hardening type bonding agent is applied over the optical imaging element, then the plastic sheet is bonded thereon, the hardening type bonding agent is hardened, and the optical imaging element 340 and the plastic sheet 311 are fixed. Patent Document 3 discloses that a light emitting element 351 is also bonded to the plastic sheet through the bonding agent.

As described above, there have hitherto been made a variety of proposals of the small-sized and thin solid-state imaging apparatus and the image sensor unit.

To summarize those related arts in terms of assembling the solid-state imaging element substrate, i.e., the solid-state imaging element chip, the protection member such as the film that covers the surface thereof, a film-shaped substrate, and a sheet-shaped substrate, Patent Documents 2 and 3 disclose that the bonding agent applied between the solid-state imaging element substrates is hardened. Further, a description of an embodiment in Patent Document 1 does not include a phrase “being hardened”, however, it is conjectured from the description of the bonding resin (sealing resin) that the bonding agent is to be hardened in this case, too.

The inventors, however, encountered with such a problem that in the case of developing the solid-state imaging apparatus, i.e., the optical sensor unit such as the fingerprint sensor in the scattered light direct reading system according to the related art, that is, by hardening the resin between the solid-state imaging element chip and the film, a minute image is not acquired, i.e., reading accuracy is low.

As a result of a progress of further researches, the inventors of the present invention found that a cause of the low reading accuracy derives from, to summarize it, a point that the film surface has waviness causing irregular refraction of the light beams entering the light receiving element portion, and consequently normal recognition is hindered. Note that, a mechanism etc. thereof will be explained in detail later on.

### SUMMARY

The present invention aims mainly at solving the problems inherent in the related arts described above. Namely, the present invention provides a solution for improving a reading accuracy of a solid-state imaging apparatus in which a solid-state imaging element chip is disposed on a film.

A solid-state imaging apparatus according to the present invention includes: a solid-state imaging element chip mounted on a film; and a resin having fluidity between the film and the solid-state imaging element chip.

To be specific, the solid-state imaging apparatus of the present invention is characterized by providing a resin having fluidity between the solid-state imaging element chip and the film. With this contrivance, light beams emitted from a luminous body are received via a fingerprint etc. serving as an object to be sensed, and, when receiving the light beams through the film, a contact surface of the film is macroscopically coincident in configuration with the object such as a finger. Therefore, even if the waviness occurs on the film, the resin having the fluidity, which is provided between the film and the solid-state imaging element chip, obviates adverse influence caused by the waviness etc. and enables highly acceptable visual recognizability to be obtained. This fact is found by the inventors of the present invention for the first time. A detailed mechanism thereof will be described with reference to the drawings in description of the embodiments.

A method of manufacturing a solid-state imaging apparatus according to the present invention includes the steps of: mounting a solid-state imaging element chip on a film; disposing a photo-curing resin between the solid-state imaging element chip and the film; and making, after disposing the photo-curing resin, irradiation of light beams that harden the photo-curing resin in areas other than an area just under a light receiving element portion of the solid-state imaging element chip without hardening the photo-curing resin at least in the area just under the light receiving element portion of the solid-state imaging element chip by use of a light shielding member, which cuts off the light beams that harden the photo-curing resin. Namely, the manufacturing method for the solid-state imaging apparatus according to the present invention has such a characteristic that the adverse influence caused by the waviness on the film surface can be prevented, and the highly acceptable visual recognizability can be obtained by disposing the resin having the fluidity at least in the area just under the light receiving element portion of the solid-state imaging element chip.

Still further, a method of manufacturing a solid-state imaging apparatus according to the present invention is a method of manufacturing a solid-state imaging apparatus having a solid-state imaging element chip mounted on a film, the method may include the steps of: mounting the solid-state imaging element chip on the film; disposing a photo-curing resin between the solid-state imaging element chip and the film; and making, after disposing the photo-curing resin, irradiation of light beams that harden a portion of the photo-curing resin extruded outside from the solid-state imaging element chip in a way that uses the solid-state imaging element chip as a mask. Namely, the manufacturing method for the solid-state imaging apparatus according to the present invention has such a characteristic that when forming the resin having the fluidity, the photo-curing resin is used as the resin, and the resin existing in the area shielded from the light beams by the solid-state imaging element chip in the way of utilizing such a nature that the solid-state imaging element chip does not transmit the light beams, is in an unhardened state, i.e., a state of having the fluidity, thereby preventing the adverse influence caused by the waviness on the film surface and enabling the highly acceptable visual recognizability to be obtained.

According to the present invention, the solid-state imaging apparatus exhibiting the excellent recognizability is obtained.

### BRIEF DESCRIPTION OF THE DRAWINGS

In the accompanying drawings:

FIG. 1 is a sectional view showing a conventional fingerprint input apparatus according to Patent Document 1;

FIGS. 2A and 2B are sectional views each illustrating a conventional image sensor according to Patent Document 2;

FIG. 3 is a sectional view showing a conventional optical sensor according to Patent Document 3;

FIGS. 4A and 4B are views each showing the whole of a solid-state imaging apparatus according to a first embodiment of the present invention;

FIGS. 5A and 5B are sectional views each showing the main portion of the solid-state imaging apparatus according to the first embodiment of the present invention;

FIG. 6 is an enlarged sectional view of an S-portion of FIG. 5B;

FIG. 7 is a plan view illustrating the main portion of the solid-state imaging apparatus according to the first embodiment;

FIGS. 8A to 8D are views each showing a manufacturing method according to the first embodiment;

FIGS. 9A and 9B are schematic views each showing an effect of the first embodiment;

FIG. 10 is an explanatory view of synthesization of a fingerprint in a scattered light direct reading system;

FIGS. 11A to 11C are explanatory schematic views each illustrating the effect of the first embodiment in greater detail;

FIG. 12 is a view showing a penetrative characteristic of polyimide;

FIGS. 13A to 13C are views each showing the main portion of a solid-state imaging apparatus according to second and third embodiments of the present invention;

FIGS. 14A to 14C are views under a manufacturing process, showing a characteristic of the third embodiment of the present invention;

FIG. 15 is a schematic view showing an effect of the third embodiment;

FIG. 16 is a sectional view showing a modified example of the second or third embodiment of the present invention;

FIGS. 17A and 17B are perspective views of a mobile phone using a solid-state imaging apparatus in a fourth embodiment of the present invention;

FIG. 18 is a plan view of the solid-state imaging apparatus in the fourth embodiment;

FIG. 19 is a view showing how the solid-state imaging apparatus in the fourth embodiment is mounted on a bending portion of a portable terminal;

FIG. 20 is a view showing how the solid-state imaging apparatus of the present invention is mounted on small-sized electronic equipment;

FIG. 21 is a view showing a solid-state imaging apparatus in a fifth embodiment of the present invention; and

FIG. 22 is an explanatory view of the apparatus in the fifth embodiment when operated.

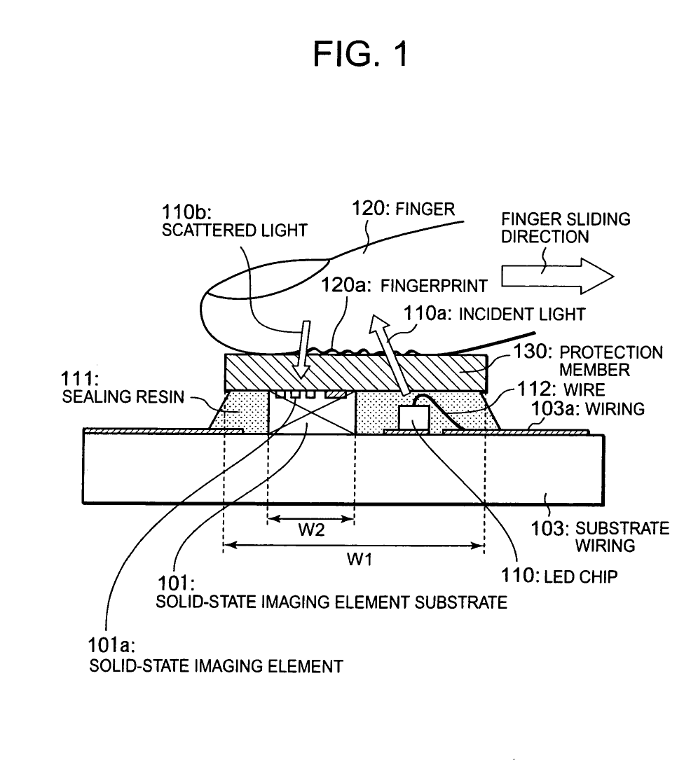

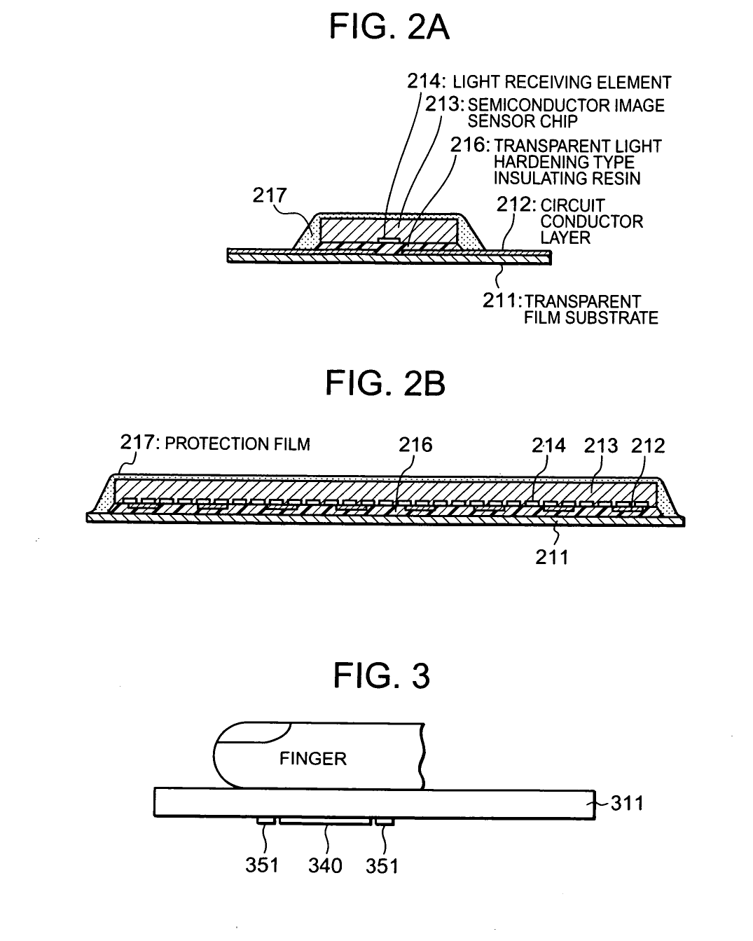

### DETAILED DESCRIPTION OF THE PREFERRED EMBODIMENTS

Embodiments of the present invention will hereinafter be described with reference to the drawings. Note that throughout all the drawings, unless specified particularly, the common components are denoted by the same reference symbols and numerals, and their explanations are properly omitted.

### First Embodiment

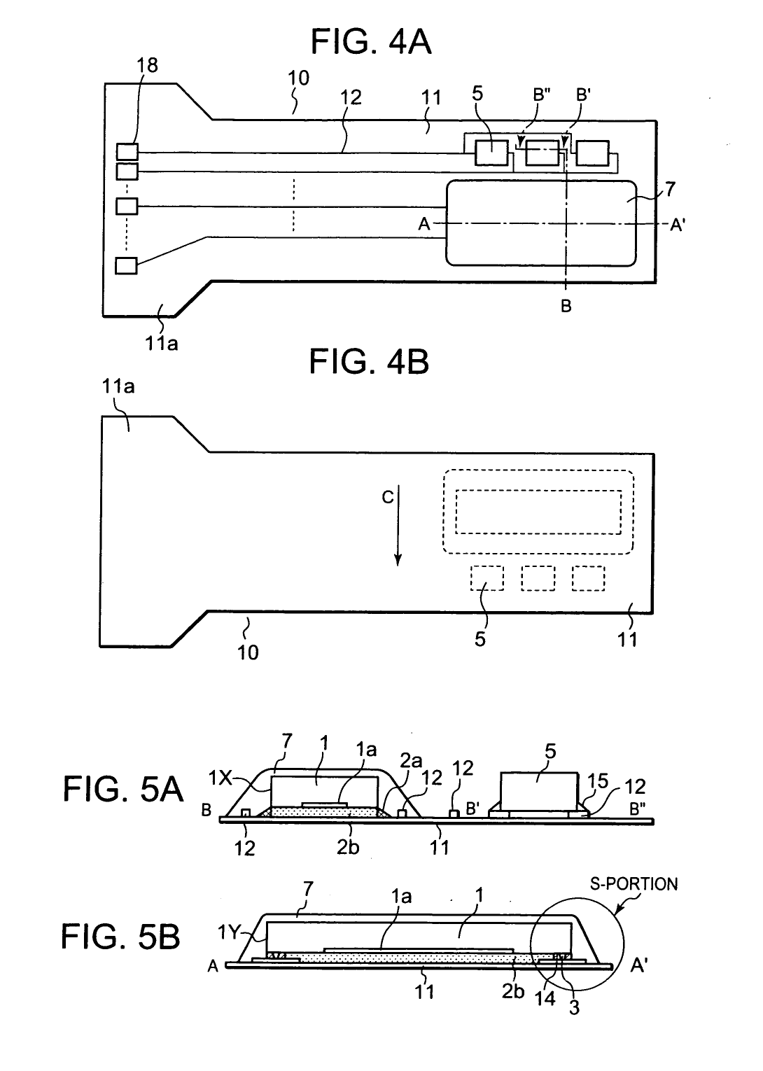

A solid-state imaging apparatus according to a first embodiment of the present invention will be described with reference to FIGS. 4A through 12. FIGS. 4A and 4B are views showing the whole of a solid-state imaging apparatus 10 according to the first embodiment of the present invention. FIG. 4A is a plan view of the solid-state imaging apparatus as viewed from a component mounting surface side. FIG. 4B is a plan view of the solid-state imaging apparatus as viewed from the opposite side to the component mounting surface, i.e., a surface touched by a finger or the like to authenticate a fingerprint or the like, namely, the solid-state imaging apparatus surface for sensing (detecting) an object, in other words, the surface on which the object to be detected is disposed or the surface touched by the object to be detected. Note that FIG. 4B illustrates the solid-state imaging apparatus 10 in a state of reversing the device 10 about an axis extending in a direction of a line A-A′ of FIG. 4A, and hence mounting components 5 etc., which will be explained later on, are reversed in their up-and-down directions. Further, illustrations of a substrate wiring 12, a terminal 18, etc. are omitted in FIG. 4B.

Referring to FIGS. 4A and 4B, in the solid-state imaging apparatus 10, a surface area of a film 11 formed of, e.g., polyimide, which is on the order of 5 micrometer to 50 micrometer in thickness, is mounted with a variety of electronic components such as the substrate wiring 12 for connecting devices, the terminal 18 for an external connection of the solid-state imaging apparatus 10, a light emitting element 5 like a light emitting diode each defined as a luminous body, and an unillustrated solid-state imaging element chip 1 protected with a sealing resin 7. Herein, the lines A-A′ and B-B′-B″ represent sectional directions for the description that will be made later on, and C indicates a direction in which the object to be sensed such as the finger is slid. It is to be noted that an area 11a of the film 11 is made wide to take out the terminal 18, however, a dimension of this width is set uniform and may also be set narrow as the case may be. Further, the substrate wiring 12, the external connection terminal 18, etc. on the film are covered with an unillustrated insulation protection material in a way that excludes the areas needed for mounting the components and for the connections with other elements. Moreover, the film 11 is not limited to a single-layered film formed of the polyimide or the like, but may take a laminated structure with a bonding agent etc. being interposed between the polyimide films.

Note that the variety of electronic components described above are mounted on the film 11, thereby performing a function as a contact optical sensor like a fingerprint sensor, in other words, a function that should be said to be a sensor module. These functions are not, however, directly related to the present invention, and hence their descriptions are omitted. Further, the film 11 is specifically formed of the polyimide or the like as the base material of a flexible printed circuit (which will hereinafter be abbreviated to FPC). Note that a quality of this base material, in other words, the material of the film 11 is not limited to the polyimide but may be, as will be mentioned later on, a flexible material that intercepts the transmission of light beams, e.g., ultra-violet rays hardening a photo-curing resin and transmits the light beams emitted from the luminous body, such as infrared-rays and red-color beams. These materials can be also applied to other organic films. Further, the film 11 and the substrate wiring 12 may be said to be a part of the components of the FPC.

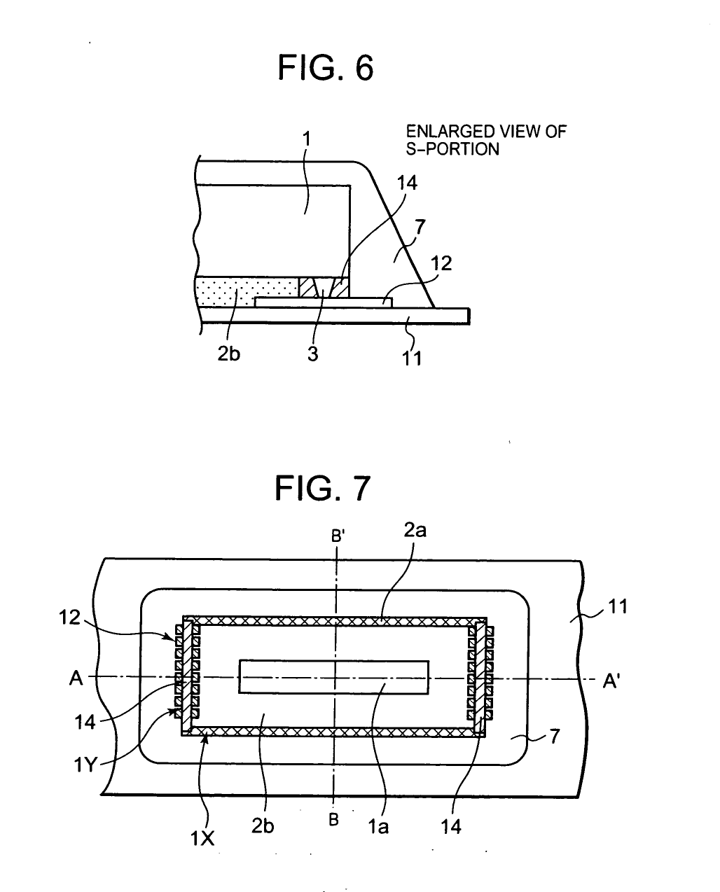

Next, the main portions in the first embodiment of the present invention will be described with reference to FIGS. 5A to 7. FIGS. 5A and 5B are each enlarged sectional views of the main portions on the component mounting side of the film 11 of the solid-state imaging apparatus 10, i.e., the enlarged sectional views taken along the line A-A′ and the line B-B′-B″ of FIG. 4A. FIG. 5A is the sectional view of a complete assembly of a B-B′-B″ portion. FIG. 5B is the sectional view of a complete assembly of an A-A′ portion. FIG. 6 is an enlarged view of an S-portion of FIG. 5B. FIG. 7 is a penetrative plan view of the portions corresponding to the B-B′ portion of FIG. 5A and the portion of FIG. 5B, i.e., the view of the solid-state imaging element chip 1 and the peripheral portion thereof. Note that FIG. 7 is the illustration given, as will be described later on, for the purpose of explaining a relationship between a resin having fluidity and a peripheral solid-state resin, or the like, and therefore the illustration of the substrate wiring 12 etc. of FIG. 5A is omitted.

Throughout these drawings, reference symbol 2b represents a resin having the fluidity that should be considered as the maximum point of the present invention. To be specific, the resin 2b is an unhardened portion of the photo-curing resin, e.g., an ultraviolet-ray hardening resin. Reference symbol 2a designates a hardened portion of the solid-state resin, e.g., the ultraviolet-ray hardening resin. Further, reference numeral 14 denotes a solid-state resin different from the resin 2a. A manufacturing method therefor will be explained later on. Moreover, reference numeral 1 represents the solid-state imaging element chip. Note that the solid-state imaging element chip is said to be a solid-state imaging element substrate in some cases, however, this terminology is not used in the present specification. Reference symbol 1a stands for a solid-state imaging element such as a complementary metal oxide semiconductor (CMOS) or a charge coupled device (CCD), and includes a multiplicity of unillustrated light receiving elements. Accordingly, the solid-state imaging element 1a is also said to be a solid-state imaging element portion of the solid-state imaging element chip, or a light receiving element portion of the solid-state imaging element chip. In the following description, the present specification will deal with the solid-state imaging element 1a or the light receiving element portion 1a in the same meaning. Further, the solid-state imaging element chip 1 includes, though not illustrated, a memory unit, a control unit, and the like in its interior, whereby image information received by the solid-state imaging element 1a is processed. Still further, the solid-state imaging element chip 1 is electrically connected to the surface portion of the film 11, in other words, connected to the substrate wiring 12 formed on the film 11 via a bump 3 provided on the side of the light receiving element portion 1a of the solid-state imaging element chip 1.

Referring further to FIG. 7, a plurality of substrate wirings 12 illustrated in FIG. 6 is provided. A plurality of unillustrated bumps 3, which are also provided corresponding to the number of these substrate wirings and are electrically connected to the substrate wirings, performs a role of input/output terminals for processing various categories of information within the solid-state imaging element chip 1. Further, a periphery of the bump 3 is covered with a solid-state resin 14. Note that the solid-state resin 14 is, as will be mentioned later on, supplied as the resin or the film in the manufacturing process in many cases and is therefore termed the resin or film 14. It is to be noted that the resin or the film is not disposed along the periphery of the bump electrode, as will be explained later on, depending on a method of mounting the bump 3, and the photo-curing resin may be used as a substitute but is not illustrated in the first embodiment.

As described above, in the first embodiment, the solid-state imaging apparatus 10 includes the resin 2b having the fluidity between the solid-state imaging element chip 1 and the film 11. Moreover, the light receiving element portion 1a of the solid-state imaging element chip is, macroscopically, said to be covered with the resin 2b having the fluidity. Still further, it is understood that a periphery of the resin 2b having the fluidity is covered with solid-state resins 2a and 14 so as not to flow from between the solid-state imaging element chip 1 and the film 11. Namely, the solid-state resins 2a and 14 are sealing resins for sealing the resin 2b having the fluidity. It may be therefore said that the periphery of the resin having the fluidity is covered with the sealing resins.

Moreover, the light emitting element 5 such as a light emitting diode is connected via a solder 15 to the substrate wiring 12 on the film 11 in order to irradiate the object such as the finger with the infrared rays, near infrared rays, red beams, etc. In other words, the luminous body is mounted on the side of the mounting surface of the solid-state imaging element chip 1 on the film 11. The luminous body may be mounted by wire bonding as will be mentioned later on and may also provided, as will further mentioned later on, in a different area without getting integral with the solid-state imaging apparatus. Moreover, the solid-state imaging element chip 1 is protected by the sealing resin 7 such as an epoxy resin. Note that if the solid-state resins 2a and 14 have a sufficient effect in sealing the fluid resin 2b, the necessity for this sealing resin 7 is eliminated.

Further, to give a different expression, the solid-state imaging element chip 1 is said to be flip-chip-mounted (which will hereinafter be abbreviated to FC (flip chip)) on the FPC. Herein, to describe the bump 3 in detail to some extent, the bump 3 involves using, e.g., a gold stud bump, plated bump, or solder bump. A method of FC-connecting the bump 3 to the substrate wiring 12 of the FPC involves employing, gold-gold pressure welding, gold-gold contact bonding, gold-soldering, a controlled collapse chip connection (C4) technique, or an anisotropic conductive film (which will hereinafter be abbreviated to ACF) connection. Reference numeral 14 represents the resin or the film which serves to stabilize the connection, attain the insulation, and mechanically hold the solid-state imaging element chip 1.

Note that, in the case of the C4 technique etc., any inconvenience may not be caused by not disposing neither the resin 14 nor the film 14. To describe it more specifically, the C4 technique is that the bump is soldered, and the connection is established without the resin or the film in some cases. In the case of adopting the C4 technique, it follows that an air gap occurs because of having none of the solid-state resin. In this case also, however, as will be mentioned later on, when filled with the resin having the fluidity, such as the ultraviolet-ray hardening resin, the resin gets effluent also from this air gap outside more than just under the solid-state imaging element chip. The outside-effluent resin is hardened, and hence any efflux of the inside resin does not occur.

Further, FIGS. 5A, 5B, and FIG. 6 are schematic enlarged sectional views, in which a scale is largely different depending on positions. To be specific, it is preferable that a distance between the film 11 and the solid-state imaging element chip 1, in other words, a thickness of the fluid resin portion be on the order of 5 micrometer to 50 micrometer. Amore preferable thickness is on the order of 10 micro meter to 50 micro meter, which is not related to a thickness of the film 11. Moreover, an upper limit of this thickness is restricted in terms of penetrability of the light for authenticating the fingerprint and the like, and a lower limit thereof is restricted in terms of a fluid function of the fluid resin that will be described later on and the like. On the other hand, the solid-state imaging element chip above the resin is considerably thicker than the resin. Since other portions are the same, the explanations thereof are omitted.

To express otherwise the configuration of FIGS. 5A to 7 that may be said to be a first core portion according to the present invention, the solid-state imaging apparatus is constructed such that the solid-state imaging element chip 1 is FC-mounted on the film 11, and the photo-curing resin such as the ultraviolet-ray hardening resin (which will hereinafter simply be referred to as ultra violet (UV) hardening resin) is filled between the solid-state imaging element chip 1 and the film 11. The solid-state imaging apparatus is also said to be an apparatus in which only the surface area from which the photo-curing resin is exposed along the outer periphery of the solid-state imaging element chip 1 is hardened, while the remaining area is the unhardened area, i.e., the resin having the fluidity. To describe it in greater detail, the hardened portion, i.e., the solid-state resin may also be said to be formed along the two face-to-face side surfaces of the rectangular solid-state imaging element chip, more specifically, along a 1X-surface of FIG. 5A or FIG. 7 and the surface facing the 1X-surface so as to cover the outer edges thereof. To give another expression, it may also be said that as for the 1X-surface of the solid-state imaging element chip, the sealing member is provided in a self-aligned manner with the outer edge of the solid-state imaging element chip. Note that the description “the sealing member is provided in a self-aligned manner with the outer edge of the solid-state imaging element chip” is now made, however, as will be mentioned later on, if a beam irradiation angle is set not in a vertical direction but in an oblique direction, the interior in the vicinity of the outer edge of the solid-state imaging element chip can be hardened. In this case also, it may also be said that the sealing member is provided in the self-aligned manner.

Additionally, to further describe the first embodiment, it may also be said that the solid-state imaging apparatus is constructed such that the solid-state imaging element chip 1 is FC-mounted on the FPC whose the base material is the polyimide, the resin having the fluidity is filled between the solid-state imaging element 1a of the solid-state imaging element chip 1 and the FPC.

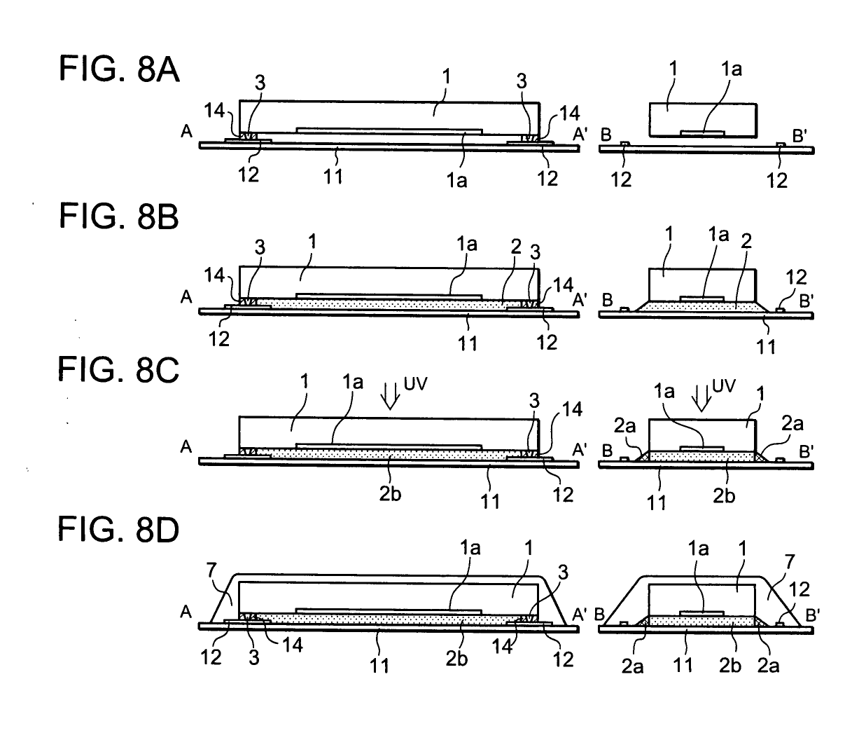

An in-depth description of the manufacturing method according to the first embodiment will be made with reference to FIGS. 8A to 8D. FIGS. 8A to 8D are views in the process of manufacturing the portions corresponding to the A-A′ portion of FIG. 5B and the B-B′ portion of FIG. 5A. A point of the explanation lies in the portion related to the way the solid-state imaging element chip 1 is mounted, and hence the description will be focused on this point.

To begin with, as illustrated in FIG. 8A, the solid-state imaging element chip 1 is electrically connected via the bumps 3 to a predetermined portion on the substrate wiring 12 on the surface portion of the film 11. It may also be said that this operation is to establish the electric connection via the bumps 3 to the predetermined portion of the substrate wiring 12 of the FPC. To describe one example more specifically, for instance, the resinous film and the resin each taking the unhardened state are disposed in the connection target portions on the substrate wiring 12, the bumps 3 are pushed against the surfaces of the film and the resin, and then the connection is established by the known method in such a way that the bumps 3 extrude the film and the resin. On this occasion, as already mentioned, the interval between the film 11 and the solid-state imaging element 1a of the solid-state imaging element chip is preferably on the order of 5 micro meter to 50 micro meter, and more preferably on the order of 10 micro meter to 50 micro meter.

Thereafter, the resin or the film 11 is hardened by the heat etc. Namely, the resin or the film 11 can involve using the resin that can be said to be a thermosetting resin in a broad sense. Note that in the view of the B-B′ plane of FIG. 8A, the solid-state imaging element chip 1 appears floating at a glance, however, this view shows the sectional view of the B-B′ portion of FIG. 4A and, for the purpose of ensuring the light receiving function, illustrates that this area contains none of the component retained thereon, which becomes an obstacle against the reception of the light.

Note that as shown in FIG. 7, the resin or the film is preferably disposed along the side surface intersecting the B-B′ portion of the solid-state imaging element chip, i.e., disposed so as to extrude slightly from the 1X-surface. In this point of view, the film is easier to be controlled. Further, the material of the resin or the film can involve employing the epoxy resin etc. Moreover, the film 11 is a film-shaped organic substance in the assembly stage and can be, after being hardened, simply said to be the solid-state resin in other words. The solid-state resin functions also as the sealing member when pouring the ultraviolet-ray hardening resin that will be described later on, and can be said to build up a part of the sealing member.

Thereafter, as illustrated in FIG. 8B, an ultraviolet-ray hardening resin 2 is filled between the solid-state imaging element 1 and the film 11. The filling is conducted by a dispenser etc. in the B-B′ direction from, e.g., the side surface of the A-A′ portion of the solid-state imaging element chip 1. As a matter of course, the resin, which is in the unhardened state at this stage, has the fluidity and is specifically in a liquid or semi-liquid state.

It is to be noted that the resin for filling can be used as the ultraviolet-ray hardening resin whose a viscosity is on the order of 0.1 to 10 Pascal·sec (Pa·s) at a room temperature, i.e., on the order of 1 to 100 Poise. Accordingly, the resin having the fluidity can be said to be the resin having the viscosity in other words. Further, it does not stick particularly to the material of the ultraviolet-ray hardening resin, however, the base material of this resin can involve using such a type of material that an acrylic radical is added to both of terminals of a backbone chain of epoxy, polyester, urethane, etc., and there occurs a reactive radical polymerized with the acrylic radical by the ultraviolet-rays. Note that the epoxy ultraviolet-ray hardening resin is preferable in terms of having no adverse influence on the solid-state imaging element even in the unhardened state.

Moreover, when filled with the ultraviolet-ray hardening resin, depending on the viscosity thereof, as illustrated in the plan view of FIG. 7, the ultraviolet-ray hardening resin might flow round outside the resin or the film 11, however, this flow-round is not indispensable. In short, it may be sufficient that the external resin 2a covers the both sides of the 1X-surface to such a degree that the internal resin having the fluidity does not flow out.

Further, when filled with the ultraviolet-ray hardening resin, in FIG. 8B, as illustrated in the view taken in the B-B′ direction, it is preferable that the resin be poured with such a quantity as to extrude outside in the B-B′ direction of the solid-state imaging element chip 1. Note that, as already mentioned, when executing the process of FIG. 8A, normally, the resin or the film 11 gets hardened continuously along the side surface in this direction, i.e., in the depthwise direction, and the resin does not flow out in the A-A′ direction of FIG. 8B. Further, a filling resin quantity can be therefore easily calculated and controlled. Note that though not illustrated in the first embodiment, if the resin 14 is not used as in the C4 technique, it is preferable to pour the resin with such a quantity as to extrude from a 1Y-surface of FIG. 5B. Note that, the description “it is preferable that the resin be poured with such a quantity as to extrude outside in the B-B′ direction of the solid-state imaging element chip 1″ has, as will be mentioned later on, a scheme that the ultraviolet-ray hardening resin can be hardened slightly deep into the interior of the solid-state imaging element chip 1 from the vicinity of the outer edge thereof by irradiating the resin with the light beams in an oblique upward direction. Accordingly, when the ultraviolet-ray hardening resin is viewed in the plane direction, it is not necessarily indispensable to extrude the ultraviolet-ray hardening resin outside the solid-state imaging element chip 1.

Next, as shown in FIG. 8C, the solid-state imaging element chip 1 is irradiated with the ultraviolet-rays (UV) substantially in the vertical downward direction from above. An intensity of the irradiation may be set corresponding to the resin to be used, i.e., may be set at a level recommended by a resin maker. Further, the setting is the same with respect to a period of irradiation time. The irradiation time may be set on the order of one second or longer in one example, which does not become a restraint in terms of manufacturing. The resin in the area of the outer peripheral portion 2a of the solid-state imaging element chip 1 is thereby hardened. On the other hand, the resin 2b at the portion just under the solid-state imaging element chip 1 including the just-under portion of the solid-state imaging element 1a, in which the irradiation of the ultraviolet-rays is intercepted by the solid-state imaging element chip 1, remains unhardened. Namely, the resin remains in the initial liquid or semi-liquid state and has the fluidity. Accordingly, the resin 2b in this area may be said to be substantially the same as the resin 2. Hence, the resin 2b can be expressed as the resin 2 by way of the notation of reference symbol in the drawing, however, in comparison with the hardened portion 2a, the resin is expressed as the resin 2b. This manufacturing method ensures the hardening of the peripheral resin, and therefore the unhardened resin does not flow out. Note that, in the case of taking the unillustrated C4 technique, as described above, the resin extruding from the 1Y-surface gets hardened, and there is no outflow of the resin. As explained above, the hardened portion performs the role of the sealing member for the unhardened resin. Further, as in the C4 technique, if the solder etc. is exposed, the solder etc. may also be said to build up a part of the sealing member. Accordingly, the sealing member is not limited to the resin and any member that hinders the resin having the fluidity from flowing out would suffice.

Moreover, the description has been given using the ultraviolet-ray hardening resin as one example of the photo-curing resin. However, without using the photo-curing resin hardened by the ultraviolet-rays, the photo-curing resin may be a resin in which the light beams are intercepted by the solid-state imaging element chip but which is not hardened under the chip, and in which the light beams are intercepted by the sheet (film) 11 as a characteristic of the light beams in use. Further, the manufacturing method has been described such that after mounting the solid-state imaging element chip 1 on the film 11, the photo-curing resin is poured and filled therebetween. Without sticking to this method, however, for example, though not illustrated, after the photo-curing resin has been disposed in a predetermined portion of the film 11, the solid-state imaging element chip 1 is mounted, namely, can be connected to the substrate wiring 12 via the bump 3. Further, the description “the solid-state imaging element chip 1 is irradiated with the light beams such as the ultraviolet-rays substantially in the vertical downward direction from above” is made above, however, the irradiation beams can irradiate in the oblique upward direction. In this case, the photo-curing resin in the peripheral portion of the solid-state imaging element chip 1 can be hardened, and the resin in the external portion can be reduced and can be further reduced to “zero” in the minimum case, thereby yielding an effect enabling the device to be downsized.

Thereafter, as illustrated in FIG. 8D, the whole portion is sealed by the sealing resin 7 such as the epoxy resin. Note that other electronic components such as the light emitting element 5 may be mounted afterward and may also be mounted in the same process as the process of mounting the solid-state imaging element chip 1. Further, these electronic components may be mounted before this process, i.e., before the process of FIG. 8A. The solid-state imaging apparatus 10 is completed by the operations described above. Note that, as already mentioned, the sealing resin 7 may not be used.

Moreover, in the case of using not the ultraviolet-ray hardening resin but the resin hardened by the light beams exhibiting much higher penetrability and in such a case that the solid-state imaging element chip becomes thin enough to transmit the ultraviolet-rays, in the process shown in FIG. 8C, an unillustrated shield is disposed especially in an upper portion or an upward portion of the solid-state imaging element 1a in the solid-state imaging element chip, whereby at least the resin in the portion just under the solid-state imaging element 1a is not hardened, while the resins in other portions can be hardened. As will be mentioned later on, this case also yields an effect in improving the recognizability. Note that, in this case, though there can arise such a suspicion that the internal resin having the fluidity gets hardened by the ultraviolet-rays etc. in an actually used state and gets disabled to perform the function thereof, as will be explained later on, normally the solid-state imaging apparatus is installed in an interior of each of housings of a mobile phone, a portable terminal, electronic equipment, etc. Accordingly, the light beams such as the ultraviolet-rays are intercepted by a thin metal portion etc. of the housings, and hence any problem in terms of the utility does not arise.

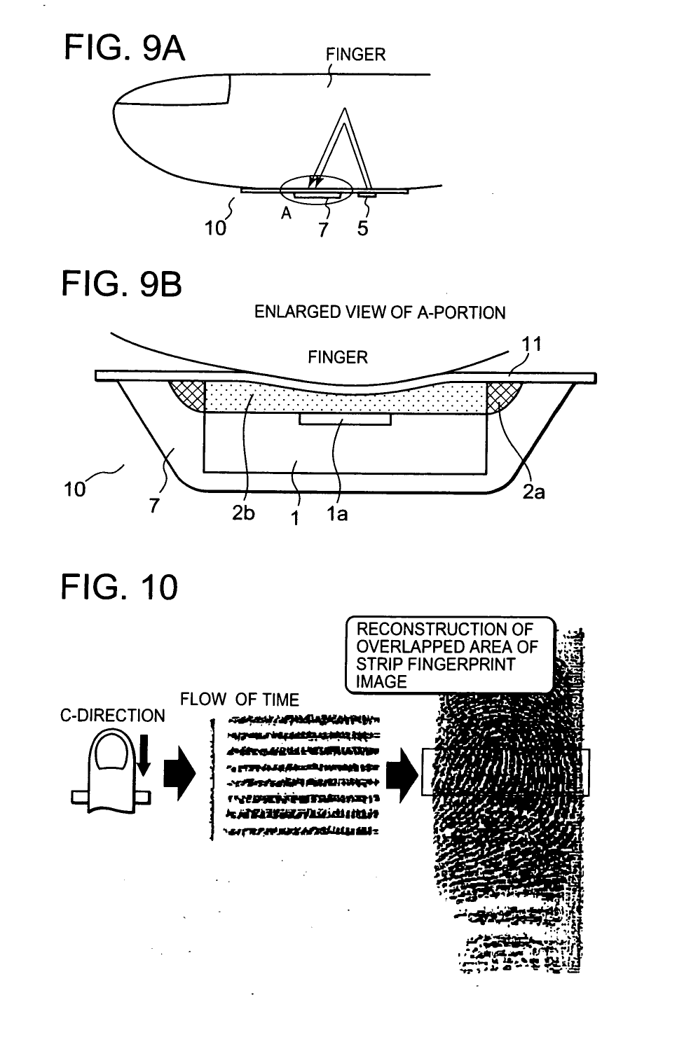

Effects of the first embodiment of the present invention will be explained with reference to the drawings. FIG. 9A is a view showing how a fingerprint is authenticated by use of the solid-state imaging apparatus 10 according to the present invention. FIG. 9B is an enlarged view of an A-portion of FIG. 9A. The fingerprint is authenticated, i.e., the fingerprint is sensed in such a way that the light beams emitted from the luminous body like the light emitting element 5, as illustrated in FIG. 9A, penetrate into the interior of the finger, and the light beams traveling via the interior of the finger and exiting the fingerprint area are sensed. Namely, in the light beams impinging on the finger from outside, the light beams traveling through the interior of the finger and exiting the fingerprint area are detected. Details thereof will be explained later on.

According to the first embodiment of the present invention, as shown in FIG. 9B, the resin having the fluidity is the resin 2b disposed between the solid-state imaging element (light receiving element portion) 1a at the portion touched by the finger and on which the finger is slid to recognize the fingerprint and the film 11, in other words, the resin 2b disposed between the FPC and the light receiving portion 1a. It is therefore possible to prevent fingerprint recognizing accuracy from declining due to waviness of the surface of the film 11 of the FPC. The thickness of the resin 2b disposed between the light receiving element portion 1a and the film 11 may be, as described earlier, on the order of 5 micro meter to 50 micro meter and more preferably 10 micro meter to 50 micro meter. Further, the description “the resin 2b has the fluidity, and it is therefore possible to prevent the fingerprint recognizing accuracy from declining due to the waviness of the surface of the film 11 of the FPC”, in other words, can imply that “the resin 2b is in the liquid or semi-liquid state or has the viscosity, and it is therefore feasible to prevent the fingerprint recognizing accuracy from declining due to the waviness of the surface of the film 11 of the FPC”. Note that the viscosity of the resin 2b is not limited to 0.1 to 10 Pascal·sec (Pa·s) but may be set to such a degree as to have the fluidity in the used state. This point will hereinafter be explained in greater detail.

FIG. 10 is an explanatory view when authenticating the fingerprint by use of the solid-state imaging element (sweep sensor) in a scattered light direct reading system. The finger is slid in a C-direction of FIG. 10. Herein, the C-direction of FIG. 10 is the same as the C-direction of FIG. 4B. A time flow is shown in the central area of FIG. 10. Overlapped portions of fragmentary pieces of strip finger images are reconstructed to form a fingerprint image. This is the basic principle of the solid-state imaging apparatus using the sweep sensor.

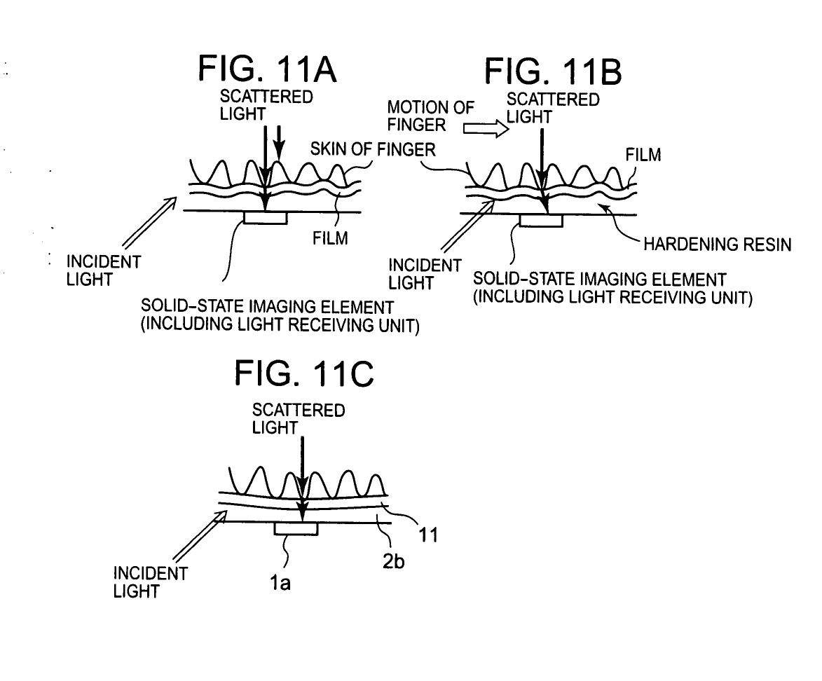

Herein, a relationship between a state of the film surface and the resin and an optical relationship will be explained with reference to FIGS. 11A, 11B, and 11C. Namely, the effects of the first embodiment of the present invention will be described in much greater detail. FIGS. 11A and 11B show examples based on the conventional technology. To be specific, this is the case in which the film has waviness, and the hardening resin exists between the film and the solid-state imaging element (light receiving element portion).

As illustrated in FIG. 11A, when the light beams getting incident on the interior of the finger penetrate the fingerprint area, a protruded area of the fingerprint directly touches the film with the result that the penetrated light beams directly enter the light receiving element portion 1a, while the recessed area of the fingerprint does not touch the film with the result that the light beams do not reach the solid-state imaging element. Piece of information of the light beams penetrating and traveling back from the protruded area of the fingerprint are collected and reorganized as shown in FIG. 10, i.e., re-synthesized into the fingerprint information. Further, FIG. 11A schematically illustrates that the film area touched by the protruded area of the fingerprint is locally comparatively flat without the waviness, and hence the light beams reach straight the solid-state imaging element.

According to the conventional technology, however, when the finger is slid and comes to the state shown in FIG. 11B, i.e., the protruded area of the fingerprint touches the wavy area of the film, the light beams are refracted in the wavy area as shown in FIG. 11B. Namely, to summarize the states shown in FIGS. 11A and 11B, it follows that the light beams are irregularly refracted. Therefore, it is difficult to search for the overlapped portion, and the re-synthesization of the fingerprint is hard to be done. Namely, it follows that the minute fingerprint image is not acquired. Note that, though not illustrated, the inventors verified the fingerprint reading accuracy of the case of setting only the hardening resin without providing the film in the process of the examination. However, excellent visual recognizability was not acquired in this case. As a result of observing the resin employed for the verification, it was confirmed that the resin surface was not smooth but rough. It is considered that this case also undergoes the irregular refraction of the light beams.

On the other hand, FIG. 11C is a schematic view showing the case of the first embodiment of the present invention, i.e., the case in which the resin 2b has the fluidity. The film 11 itself has the waviness, however, even if the film 11 is wavy, the resin 2b thereunder has the fluidity. Therefore, the waviness decreases along the finger skin by dint of a finger pressure or shifts outside the light receiving area of the solid-state imaging element (light receiving element portion) 1a, so it is considered that the minute fingerprint image can be acquired by facilitating the re-synthesization of the fingerprint image without any occurrence of a change in refraction. What has been described so far is a first finding by the inventors of the present invention.

Note that, the result of researches by the inventors of the present invention shows that the surface waviness of the film 11 is easy to occur most when FC-mounting the solid-state imaging element chip 1 or the like on the FPC. To describe it in greater detail, there is a necessity of attaining metal junctions between the bumps of the solid-state imaging element chip (which will hereinafter be simply referred to as chip 1) and the substrate wirings 12 of the FPC, and hence the waviness occurs when directly heating the chip 1 and the FPC. Further, the soldering conducted when mounting the electronic components etc. to the substrate wirings 12 on the FPC is the process becoming a factor of causing the waviness. Accordingly, those processes are indispensable for obtaining the thin and flexible product, and it is therefore difficult to obviate the waviness. Moreover, in other words, it may also be said that the waviness is produced when heating the organic film, and hence, even if the film is not constructed as the FPC, namely, as disclosed in Patent Document 1, it is conjectured that the waviness occurs on the occasion of assembling widely a protection member simply based on the organic film. The inventors of the present invention provide, as the minute image obtaining method even when the waviness exists, a method of disposing the resin 2b having the fluidity between the light receiving element portion 1a of the solid-state imaging element chip and the film 11. It is therefore sufficient that the resin having the fluidity exists at least in the area just under the light receiving element portion 1a.

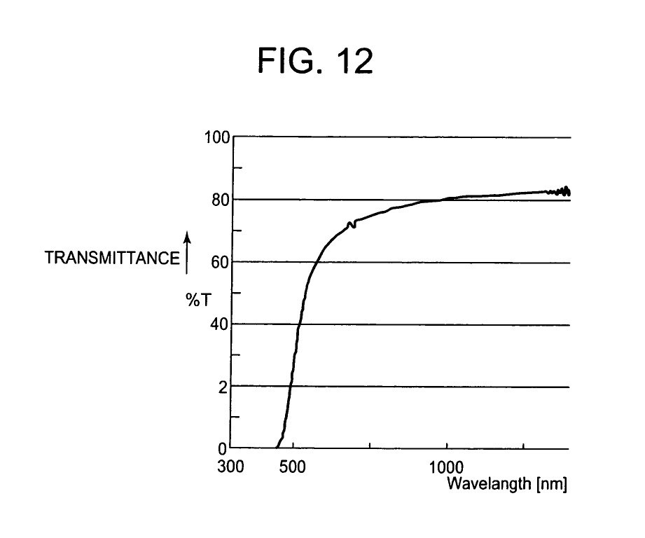

Further, the polyimide has been exemplified for the use of the film 11 of the first embodiment, i.e., exemplified as the base material of the FPC, however, the polyimide cuts off the ultraviolet-rays (represented by a wavelength of 380 nm or less in FIG. 12) but transmits the infrared-rays. Therefore, the polyimide is used for the film of the first embodiment, whereby the ultraviolet-rays emitted from the natural world are cut off in the usage state after being manufactured, any progress of the hardening of the UV hardening resin is not made, and there is a long-term preserving effect enabling the state of having the fluidity, i.e., the liquid/semi-liquid/viscous state to be maintained.

### Second Embodiment

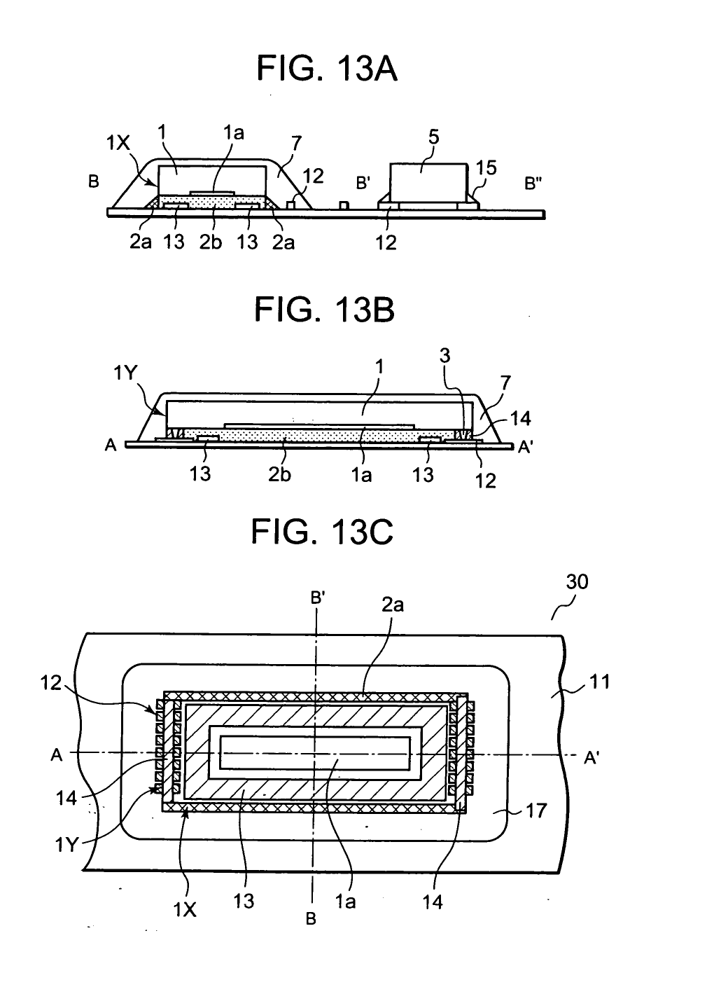

Next, a second embodiment of the present invention will be described with reference to FIGS. 13A to 13C in a way that focuses on different portions from those in the first embodiment of the present invention. To give a brief explanation of a solid-state imaging apparatus 30 in the second embodiment, the solid-state imaging apparatus 30 is characterized by adding (forming) a light shielding wiring 13 to the first embodiment. It is preferable that the light shielding wiring 13 be formed in a frame-like shape as shown in FIG. 13C. The following is a slightly detailed explanation.

FIG. 13A is a view corresponding to FIG. 5A in the first embodiment. A difference from the first embodiment is that the light shielding wiring 13 is provided along the periphery, spaced from a just-under surface of the light receiving element portion 1a, of the surface contiguous to the resin 2b having the fluidity on the film 11. This is the same as the light shielding wiring 13 of FIG. 13B. FIG. 13C shows an enlarged plan view (schematic sectional view) of the portion corresponding to the portion of FIG. 7. The light shielding wiring 13 circumscribes in the frame-like shape the periphery of the light receiving element portion 1a. This configuration blocks extraneous light other than the light beams incident on the solid-state imaging element 1a via the finger from the light emitting element 5. Namely, since a rate of the scattered light from the finger increases, an S/N (signal-to-noise) ratio of the electric signal of the fingerprint image can be improved, and a more preferable image can be acquired, which is a particular effect not yielded in the first embodiment.

Note that the light shielding wiring, though described as the wiring for light shielding, may be formed of the same material and with the same thickness as those of the substrate wiring 12 employed for the normal electric connection. Further, the thickness thereof may be changed according to the necessity. Still further, the material can be also replaced. Note that, the manufacturing method is basically the same as in the first embodiment, the difference is a point about whether the element including the light shielding wiring 13 provided on the film 11 is prepared or not, and hence a detailed explanation of the manufacturing method is omitted.

Moreover, the description “it is preferable that the light shielding wiring be formed in the frame-like shape” has been made, however, the shape is not necessarily frame-like, and, as a matter of course, a break may be formed midway. For others, the shape can be, as a matter of course, modified in a variety of forms such as a partly-thinned-shape.

### Third Embodiment

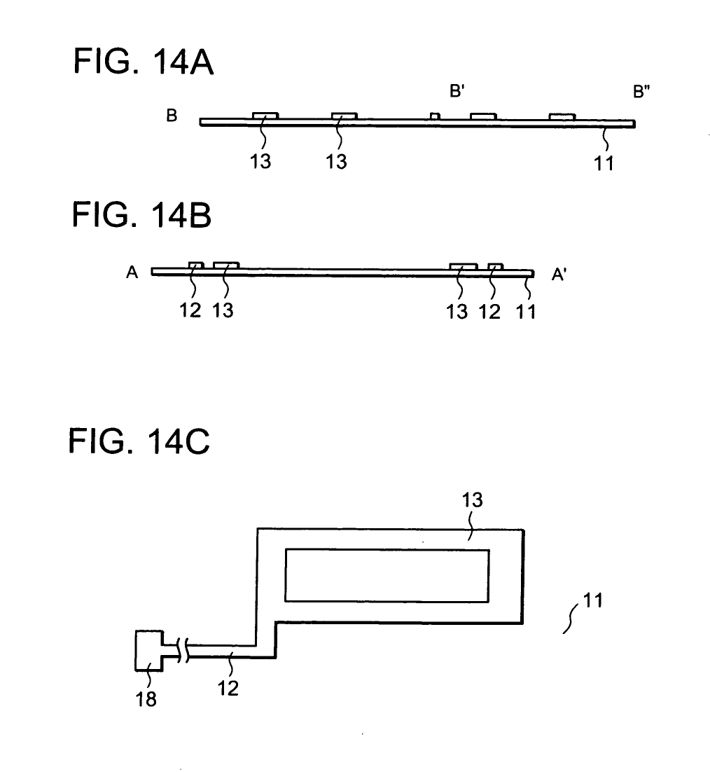

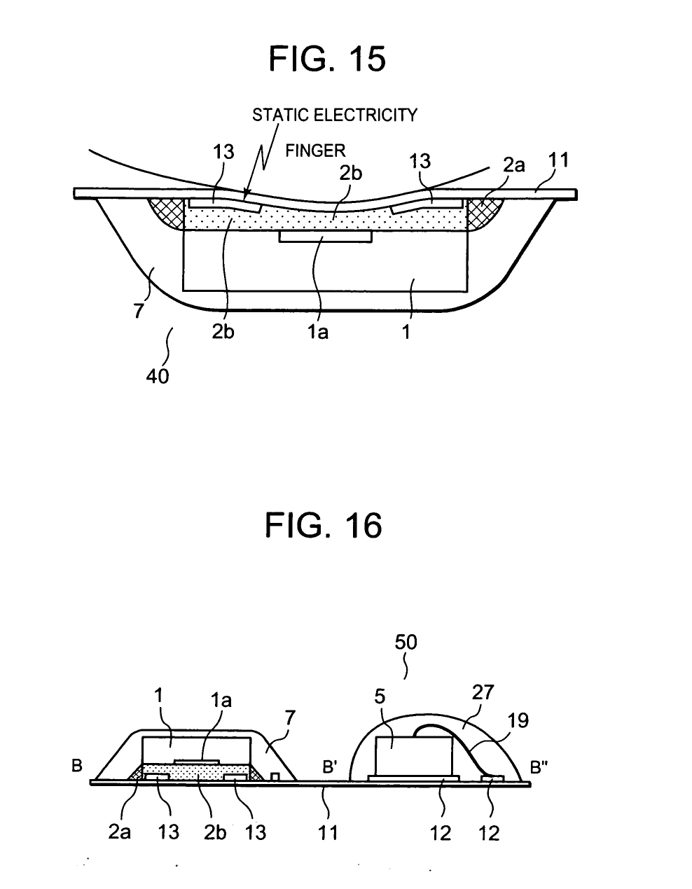

A third embodiment of the present invention will be explained with reference to FIGS. 14A to 15 in addition to FIGS. 13A to 13C. In short, a feature of a solid-state imaging apparatus 40 in the third embodiment is that the light shielding wiring 13 in the second embodiment is connected to an earth terminal or the like, thereby having an electrostatic breakdown preventing effect.

The sectional view taken along the line A-A′ and the sectional view taken along the line B-B′-B″ in the third embodiment are the same as FIGS. 13A and 13B. A different point is that those sectional views are plan views. FIGS. 14A, 14B, and 14C illustrate portions in the middle of the manufacturing process in order to clarify the different point. FIGS. 14A and 14B are sectional views of the film 11 etc. before mounting the solid-state imaging element chip 1. FIGS. 14A and 14B are, though not illustrated in the discussion on the second embodiment, the same as the drawings in the second embodiment. The difference is, as shown in the plan view of FIG. 14C, that the light shielding wiring 13 is connected to the terminal 18 via the substrate wiring 12 on the film 11. Note that the terminal 18 is connected to a terminal of unillustrated external equipment and to a conductive portion etc. of the external equipment and is earthed.

An effect of the solid-state imaging apparatus 40 according to the third embodiment of the present invention will be explained with reference to FIG. 15. According to the third embodiment, because of including the light shielding wiring 13 serving also as the earth wiring 13, in addition to the improvement of the S/N ratio of the electric signal of the fingerprint image described in the second embodiment, there is yielded a particular effect of exerting none of the adverse influence caused by the static electricity upon the solid-state imaging element chip 1 and the light receiving element portion 1a thereof by building up a discharge path for the static electricity accumulated in the human body such as the finger.

### Modified Examples of First, Second, and Third Embodiments

The embodiments described above have exemplified the light emitting element 5 soldered onto the substrate wiring 12 of the film 11. Namely, the example of surface-mounting the light emitting element 5 on the FPC has been exemplified, however, this light emitting element 5 can be mounted by wire bonding. FIG. 16 illustrates an example of a solid-state imaging apparatus 50 in which the light emitting element 5 is mounted by the wire bonding that involves using a bonding wire 19 in the second or third embodiment. The mounting by the wire bonding also has an effect of attaining further downsizing than by mounting a discrete light emitting element, i.e., an in-package light emitting element. Note that reference numeral 27 of FIG. 16 designates a protection resin of a wire bonding connecting portion. Further, in this case, the light emitting element 5 is often connected entirely to the substrate wiring 12, and hence, though concerned about whether or not the light beams can reach the object such as the finger, there is no problem in terms of the practical use because of having the light beams reflected by the protection resin 27 and entering the finger.

### Fourth Embodiment

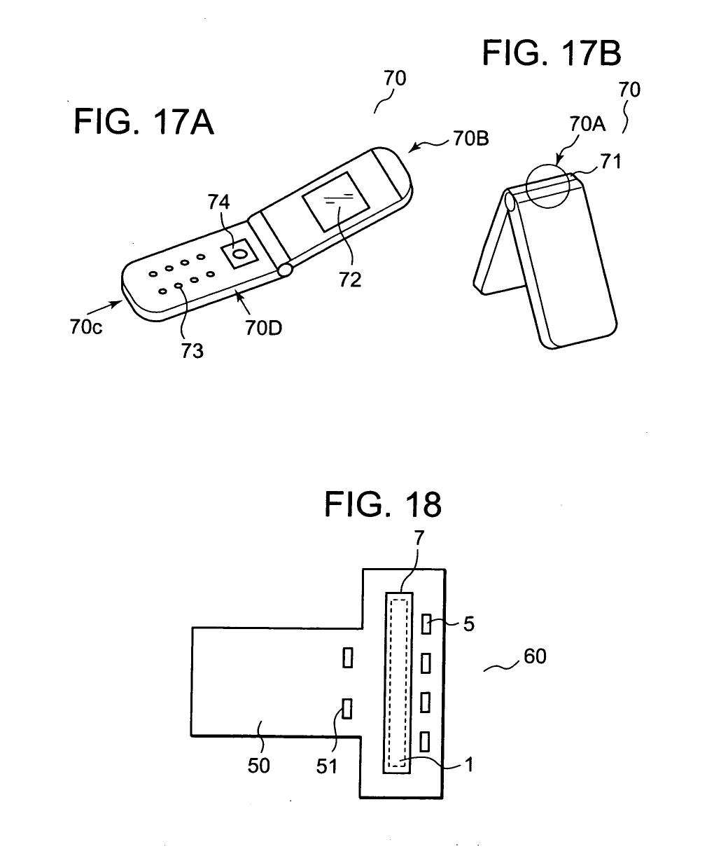

Next, an embodiment of mounting the solid-state imaging apparatus on the portable terminal such as the mobile phone, i.e., the portable electronic equipment, will be described with reference to FIGS. 17A to 19. FIGS. 17A and 17B show an example of mounting the solid-state imaging apparatus according to the present invention described above on a mobile phone 70. As for the mounting portions, the solid-state imaging apparatus can be, as a matter of course, mounted on a main screen portion including a button 73, a click portion 74, etc., however, this scheme does not provide a conspicuous effect in the flexibility of the present invention.

Such being the case, as for the mounting portion, an example of mounting the solid-state imaging apparatus on a bending portion, i.e., a portion designated by 70A of the mobile phone 70 will hereinafter be described. Note that the mounting portion may, as a matter of course, include side surface portions 70B, 70C, 70D, etc.

FIG. 18 is a plan view of a solid-state imaging apparatus 60 of the present invention. FIG. 18 shows elements of the electronic components such as the light emitting element 5, the solid-state imaging element chip 1, the sealing resin 7, and a capacitor 51. Note that the illustrations of the wirings and the terminals on the film are omitted, however, the terminal portions exist in a width-narrow direction of a film 50. FIG. 18 illustrates an example in which the width of the terminal portions may be small unlike FIGS. 4A and 4B. Note that the characteristic scheme of the present invention such as using the resin having the fluidity involve employing, as a matter of course, any one of the first through third embodiments or any one of the modified examples thereof, and hence the detailed description of the manufacturing method etc. is omitted.

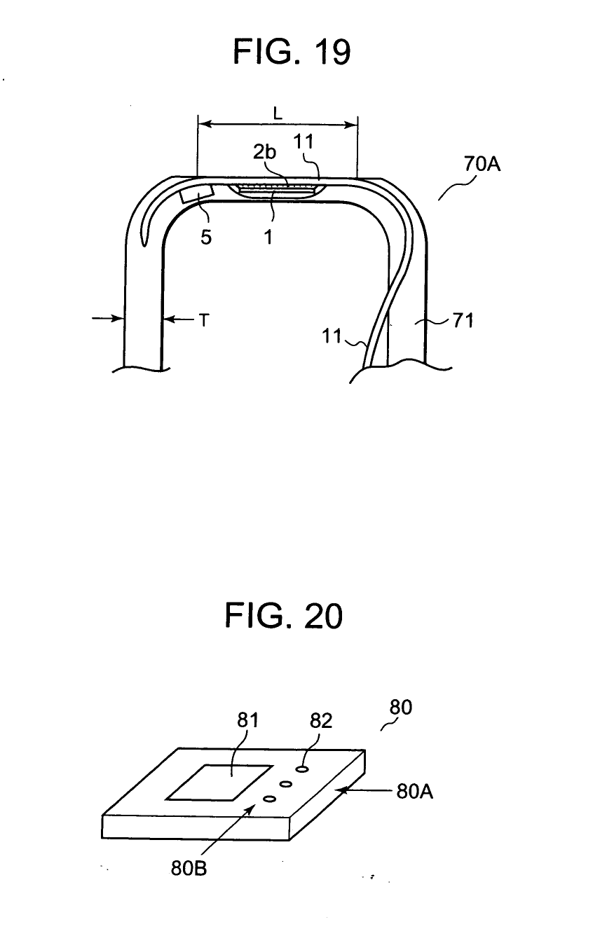

FIG. 19 is a sectional view showing that the solid-state imaging apparatus 60 of the present invention is mounted on the bending portion 70A of the mobile phone. According to the present invention, as shown in FIG. 19, the solid-state imaging apparatus 60 can be effectively mounted on the bending portion 70A of a phone housing 71 of the mobile phone. To describe one example by giving more specific numerical values, for example, if a dimension of a thickness T of the phone housing is set to approximately 1 mm, this is the thickness to such a degree that the solid-state imaging apparatus according to the embodiments of the present invention is set in substantially as shown in the drawing. Further, as for a dimension for mounting the solid-state imaging element 1 and the fluidity resin 2b each functioning as the fingerprint sensor portion, i.e., as for a dimension of the B-B′ portion of FIGS. 5A and 13A, a flat portion of approximately 3 to 4 mm is sufficient as the fingerprint sensor touched by the finger. In this case, the light emitting element 5 etc. can be disposed, as depicted by a dimension L in FIG. 19, in a half-bent portion. The configuration of the solid-state imaging apparatus can be, as a matter of course, arbitrarily determined from within the configurations of FIGS. 18, 4A, and 4B and other configurations, depending on the fitting position thereof.

As described above, according to the present invention, the solid-state imaging apparatus can be mounted effectively on the side surface and the bending portion of the mobile terminal such as the mobile phone and of the portable electronic equipment, which contributes to downsizing of the portable electronic equipment on the whole. To grasp it broadly, it may also be said that the present invention contributes to downsizing of the electronic equipment.

### Modified Example of Fourth Embodiment

Note that, FIG. 20 shows an example of mounting the solid-state imaging apparatus on the side surface of small-sized electronic equipment 80 such as a handheld small-sized personal computer and a portable game machine, and also illustrates a modified example of the fourth embodiment. As a matter of course, the solid-state imaging apparatus of the present invention can be mounted on a surface 80B including a display portion 81, an operation button 82, etc., however, if a space of this surface is not enough, the solid-state imaging apparatus can be mounted on a side surface 80A or the like. Note that a method on this occasion is the same as in the fourth embodiment, and therefore its detailed explanation is omitted. The electronic equipment is much thicker than the housing of the mobile phone described earlier, so the finger can easily touch the side surface, thereby yielding an effect in facilitating the authentication of the fingerprint.

### Fifth Embodiment

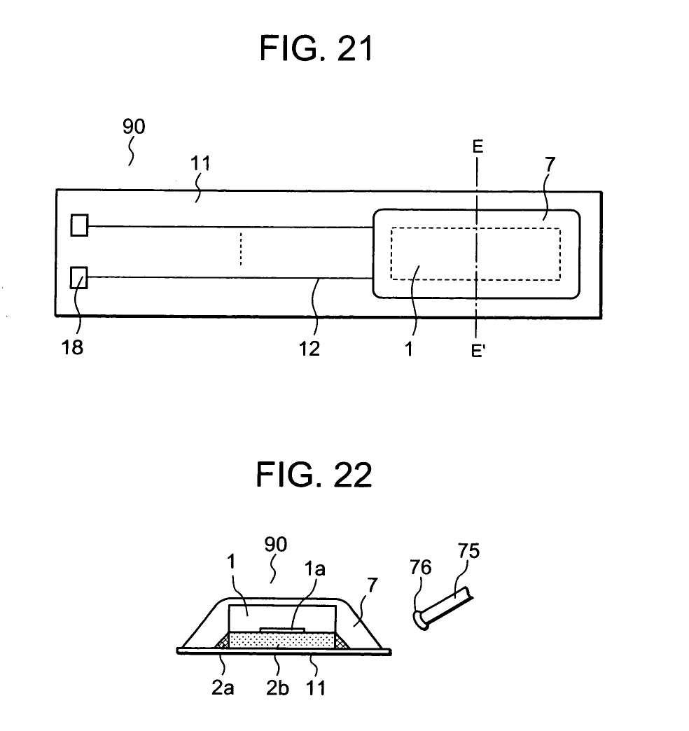

FIGS. 21 and 22 illustrate the solid-state imaging apparatus according to a fifth embodiment of the present invention, in which the light emitting element is not mounted on the film 11. Namely, in the solid-state imaging apparatus according to the present invention, it is not indispensable for the light emitting element to be mounted on the film. FIG. 21 illustrates a solid-state imaging apparatus 90 according to the present invention, which includes the solid-state imaging element chip 1, the sealing resin 7, the substrate wiring 12, and the terminal 18. Note that the illustrations of the electronic components etc. are omitted in FIG. 21.

FIG. 22 is an enlarged sectional view of an E-E′ portion of FIG. 21. A difference from FIG. 5A is, in addition to the absence of the light emitting element, that an optical fiber 75 whose tip is provided with a light scattering portion 76 etc. is housed in an unillustrated hold housing and is thus disposed on the side surface of the solid-state imaging apparatus 90, e.g., in a position vicinal to the area provided with the light emitting element 5 as in the first embodiment etc., thereby supplying the light beams therefrom. This is one example enabling the fingerprint to be authenticated. This method is useful for such an occasion that the equipment like the mobile phone and the portable terminal, which is provided with the solid-state imaging apparatus, is increasingly downsized and is deficient in terms of the space for disposing the light emitting element.

Note that the discussions on the embodiments of the present invention have focused on the example of utilizing the solid-state imaging apparatus for reading the fingerprint. Further discussion has been made on the example of mounting the solid-state imaging apparatus on the mobile phone and the small-sized electronic equipment. However, the applicable range of the solid-state imaging apparatus according to the present invention is not limited to reading of the fingerprint. For example, the solid-state imaging apparatus is highly useful for the application as an optical sensor apparatus for detecting a surface state by irradiating an object having the ruggedness (the protruded and recessed areas) on the surface such as on the face and the skin of the human body and other living creatures with the light beams from outside, then causing the light beams to penetrate the interior thereof and detecting the light beams traveling back from the protruded area through contact. Moreover, the application is not limited to this scheme but can broadly extend to the application as the optical sensor apparatus for detecting a shape of the object having the ruggedness on the surface by getting the object to touch the film 11 or disposing the object on the film 11 and irradiating the object with the light beams from outside.

Still further, the discussion on the present invention has focused on the solid-state imaging apparatus using the sweep sensor. It is, however, considered useful to provide the resin having the fluidity as in the present invention from a point of view of further improving the visual recognizability also in the solid-state imaging apparatus employing not the sweep sensor but a two-dimensional sensor. Accordingly, the applicable range of the present invention is not limited to the solid-state imaging apparatus using the sweep sensor. The discussion on the present invention has been properly made so far with reference to the drawings, however, the present invention can be, as a matter of course, without sticking to the contents disclosed above, properly modified and changed within the scope of the idea of the invention.

What is claimed is:

1. A solid-state imaging apparatus comprising:
a solid-state imaging element chip mounted on a film; and
a resin having fluidity between the film and the solid-state imaging element chip.

2. A solid-state imaging apparatus according to claim 1, further comprising
a light receiving element portion provided on a side of a surface of the solid-state imaging element chip to be mounted on the film, wherein
the resin having the fluidity is provided at least between the light receiving element portion and the film.

3. A solid-state imaging apparatus according to claim 1, wherein
a periphery of the resin having the fluidity is covered with sealing members.

4. A solid-state imaging apparatus according to claim 3, wherein
at least a part of the sealing members is a resin formed of the same principal constituent as that of the resin having the fluidity, and is provided in a self-aligned manner with an outer edge of the solid-state imaging element chip.

5. A solid-state imaging apparatus according to claim 1, wherein
the resin having the fluidity comprises a photo-curing resin.

6. A solid-state imaging apparatus according to claim 1, wherein:
the solid-state imaging element chip has a rectangular flat surface; and
the solid-state imaging apparatus further comprises
a sealing member formed of a resin different from the resin having the fluidity in a side portion of the rectangular flat surface having a bump of the solid-state imaging element chip.

7. A solid-state imaging apparatus according to claim 1, wherein
the film is formed of a material that cuts off light beams having a wavelength which hardens the photo-curing resin.

8. A solid-state imaging apparatus according to claim 1, wherein
the film is polyimide.

9. A solid-state imaging apparatus according claim 8, wherein
a thickness of the film is from 5 micro meter to 50 micro meter.

10. A solid-state imaging apparatus according to claim 1, wherein
the resin having the fluidity is filled with the thickness from 5 micro meter to 50 micro meter between the film and the solid-state imaging element chip.

11. A solid-state imaging apparatus according to claim 2, wherein
the resin having the fluidity is filled with the thickness from 5 micro meter to 50 micro meter between the film and the light receiving element portion of the solid-state imaging element chip.

12. A solid-state imaging apparatus according to claim 1, further comprising
a light shielding pattern on a surface portion of the film on which the solid-state imaging element chip is mounted.

13. A solid-state imaging apparatus according to claim 1, further comprising
an earthing pattern on a surface portion of the film on which the solid-state imaging element chip is mounted.

14. An electronic equipment using the solid-state imaging apparatus according to claim 1.

15. An electronic equipment according to claim 14, wherein
one surface of the film of the solid-state imaging apparatus is exposed to at least one of a side surface portion and a bending portion of the electronic equipment.

16. A method of manufacturing a solid-state imaging apparatus having a solid-state imaging element chip mounted on a film, comprising the steps of:
mounting the solid-state imaging element chip on the film;
disposing a-photo-curing resin between the solid-state imaging element chip and the film;
disposing a light shielding member, after the disposing the photo-curing resin, at least one of on and above a light receiving element portion of the solid-state imaging element chip; and
hardening, by being irradiated with light beams, the photo-curing resin in areas other than an area just under the light receiving element portion of the solid-state imaging element chip without hardening at least the photo-curing resin in the area just under the light receiving element portion of the solid-state imaging element chip.

17. A method of manufacturing a solid-state imaging apparatus according to claim 16, wherein:
the light shielding member is the solid-state imaging element chip; and
the method further comprises the step of hardening a portion of the photo-curing resin outside from the solid-state imaging element chip by being irradiated with light beams using the solid-state imaging element as a mask.
